(19) United States
(12) Patent Application Publication
(10) Pub. No.: US 2010/0085518 A1
(43) Pub. Date: Apr. 8, 2010

(54) PHOTO-SENSITIVE RESIN COMPOSITION FOR BLACK MATRIX, BLACK MATRIX PRODUCED BY THE COMPOSITION AND LIQUID CRYSTAL DISPLAY INCLUDING THE BLACK MATRIX

(76) Inventors: Kyung-Soo Choi, Gyeonggi-do (KR); Yoon-Hee Heo, Seoul (KR); Dong-Chang Choi, Daejeon Metropolitan City (KR); Ho-Chan Ji, Daejeon Metropolitan City (KR); Geun-Young Cha, Daejeon Metropolitan City (KR); Dae-Hyun Kim, Gyeonggi-do (KR)

Correspondence Address: MCKENNA LONG & ALDRIDGE LLP, 1900 K STREET, NW, WASHINGTON, DC, 20006, US

(21) Appl. No.: 12/449,660

(22) PCT Filed: Feb. 21, 2008
(86) PCT No.: PCT/KR2008/001011

§ 371 Date: Aug. 20, 2009

(30) Foreign Application Priority Data
Feb. 21, 2007 (KR) 1020070017486

(51) Int. Cl. G02F 1/1333; G03F 7/004; G03F 1/00

(52) U.S. Cl. 349/110; 430/286.1; 430/280.1; 430/7

(57) ABSTRACT

The present invention relates to a photosensitive resin composition for a black matrix, a black matrix produced by the composition and a liquid crystal display including the black matrix. The resin composition for a black matrix comprising a fluorene-based resin polymer as a resin binder has high sensitivity and optical density, and excellent development adherence.

### TECHNICAL FIELD

The present invention relates to a photosensitive resin composition for a black matrix of a liquid crystal display (hereinafter, referred to as “LCD”), a black matrix produced by the composition and a liquid crystal display including the black matrix. More particularly, the present invention relates to a resin composition for a black matrix comprising a fluorene-based resin, thereby having high sensitivity and optical density, and excellent development adherence.

This application claims priority from Korean Patent Application No. 10-2007-17486 filed on Feb. 21, 2007 in the KIPO, the disclosure of which is incorporated herein by reference in its entirety.

### BACKGROUND ART

In order to satisfy properties required in LCD such as high image quality and high contrast, there is a need to form a black matrix (BM) having an excellent light-shielding property. Generally, to form the black matrix, a multi-step process is needed as follows: a film of metal such as chromium is produced by a vacuum deposition process, a photoresist is applied to the metal film, exposed, developed, etched and the photoresist is removed from the metal film. There are advantages in that the black matrix produced by the process is thin and has a high light-shielding property. However, since the black matrix has a high light-reflectance, an additional process is required. Further, since the black matrix is produced by the multi-step process, the production cost increases, and environmental problems are caused due to the use of metals. Further, in IPS (In-Plain Switching) mode, the black matrix having low volume resistance is required. Thus, a resin black matrix has been widely used. The resin black matrix consists of a light shielding material, a binder resin, a multi-functional monomer, a photoinitiator, a solvent or the like.

In order to have a sufficient light shielding property, the known black matrix needs a sufficient amount of a light-shielding pigment. However, use of the light-shielding pigment in a higher concentration has been a main factor to deteriorate the sensitivity and stability upon development.

Many studies have been conducted to develop various kinds of binder resins for the black matrix skeleton to solve such problems. For example, Korean Patent Publication No. 2003-0093514 suggested an acrylic based binder having a reactive group, and Korean Patent Publication No. 2005-0088119 suggested an acrylic copolymer binder resin having a carboxyl group. In particular, Japanese Unexamined Patent Publication Nos. 5-339356 and 8-278630, and Korean Patent Publication No. 2000-55255 disclose a cardo-based binder resin. Currently, the cardo-based binder resin has been widely used for the composition for a black matrix having high sensitivity, excellent heat-resistance, and chemical-resistance or the like. However, the known cardo-based binder resin is prepared by the reaction of diol compound and acid dianhydride. Therefore, as the binder has a higher molecular weight, its acid value becomes higher, leading to much damage in the edges of a pattern upon development. Thus, it is difficult to obtain stable patterns. Further, the adherence is deteriorated due to its bulky molecular structure.

### DISCLOSURE

### Technical Problem

Accordingly, in order to solve the above problems in the prior art, it is an object of the present invention to provide a photo-sensitive resin composition for a black matrix having a sufficient light-shielding property, and high sensitivity and adherence, a black matrix produced by the composition and a liquid crystal display including the black matrix.

### Technical Solution

In order to achieve the above object, the present invention provides a photo-sensitive resin composition for a black matrix, comprising

a) 1 to 70% by weight of a light shielding material containing a coloring agent;

b) 1 to 30% by weight of a resin binder having a repeating unit of the following Formula 1;

c) 1 to 30% by weight of a multi-functional monomer having an ethylenic unsaturated bond;

d) 1 to 30% by weight of a photopolymerization initiator; and

e) a residual amount of a solvent.

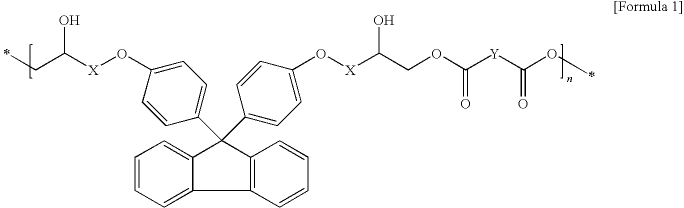

wherein X is one selected from the group consisting of alkylene having 1 to 3 carbon atoms, ethylene oxide and propylene oxide, and

Y is one selected from the group consisting of cyclohexane, cyclohexene, benzene, and alkylene having 1 to 3 carbon atoms.

Further, the present invention provides a black matrix produced by the photo-sensitive resin composition.

Further, the present invention provides a color filter and a liquid crystal display including the black matrix.

### Advantageous Effects

The photo-sensitive resin composition for a black matrix according to the present invention has sufficient light-shielding property, a stable pattern shape and sufficient developmental margin, thereby forming a black matrix having improved proccessability.

### DESCRIPTION OF DRAWINGS

FIG. 1 is an optical microscope picture of a black matrix pattern produced by a photo-sensitive resin composition for a black matrix of Example 1; and

FIG. 2 is an optical microscope picture of a black matrix pattern produced by a photo-sensitive resin composition for a black matrix of Comparative Example 1.

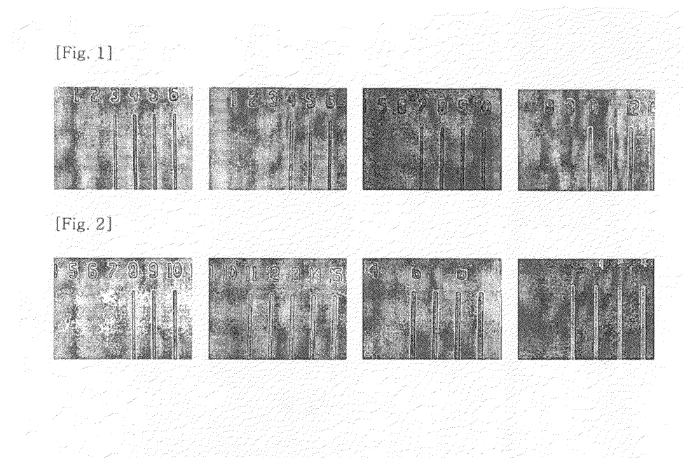

### BEST MODE

Hereinafter, the present invention will be described in detail.

Formula 1 may be represented by the following Formula 2, when X is methylene and Y is cyclohexene.

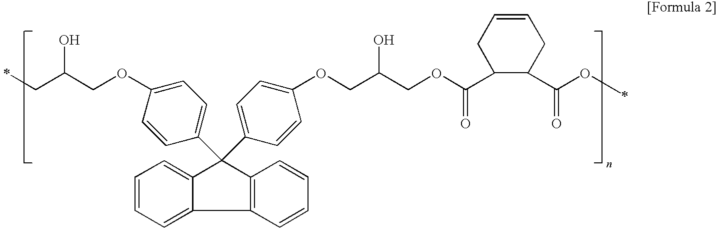

The coloring agent contained in the light shielding material of the photo-sensitive resin composition for a black matrix may be one or more kinds selected from organic pigments such as black pigment, red pigment, yellow pigment, blue pigment, and violet pigment. Examples of the black pigment include carbon black and titan black, and examples of the carbon black include furnace black such as SAF, ISAF, HAF, FEF, SRF, and GPF; thermal black such as FT and MT; and acetylene black, preferably, carbon black pigment in terms of light-shielding property and economic efficiency.

The light shielding material is preferably contained in an amount of 1 to 70% by weight, based on the total weight of the photo-sensitive resin composition for a black matrix. The content of the light shielding material may affect an optical density (OD). In accordance with this, it is preferable that the optical density is high. Therefore, if the content of the light shielding material is low, the optical density decreases, leading to poor light-shielding property. If the content of the light shielding material is high, the optical density is preferable, however, leading to poor proccessability.

The resin binder contained in the photo-sensitive resin composition for a black matrix is a fluorene-based resin polymer having a repeating unit of Formula 1, and can be prepared by condensation reaction of a diepoxy compound containing a fluorene group, represented by the following Formula 3 and a diacid compound having such a structure that both ends of one selected from benzene, cyclohexane, cyclohexene, norbornene and alkane having 3 to 10 carbon atoms are substituted with two acids.

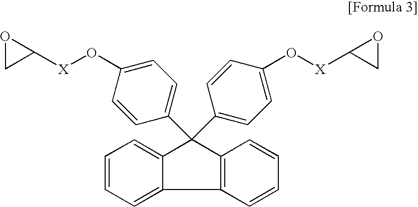

wherein X is one selected from alkylene having 1 to 3 carbon atoms, ethylene oxide and propylene oxide.

Specifically, in the case where X in Formula 3 is propylene oxide, it can be represented by the following Formula 4.

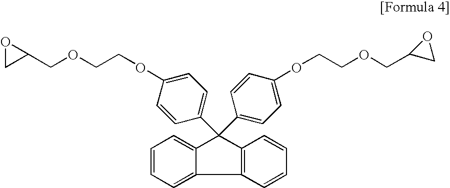

Further, the diacid compound contained in the fluorene-based resin polymer according to the present invention has such a structure that both ends of one selected from benzene, cyclohexane, cyclohexene, norbornene and alkane having 3 to 10 carbon atoms are substituted with two acids, and may include the following compounds, preferably a compound having a cyclic group to improve an adherence on a substrate while the pattern undergoes developing process.

Examples of the diacid compound preferably include cis-4-cyclohexene-1,2-dicarboxylic acid, cis-5-norbornene-endo-2,3-dicarboxylic acid, succinic acid, isophthalic acid, phthalic acid, 1,2-cyclohexanedicarboxylic acid, 1,2-phenylene diacetic acid, 1,2-phenylene dioxy diacetic acid, and 1,4-cyclohexanedicarboxylic acid, which can be represented by the following compounds.

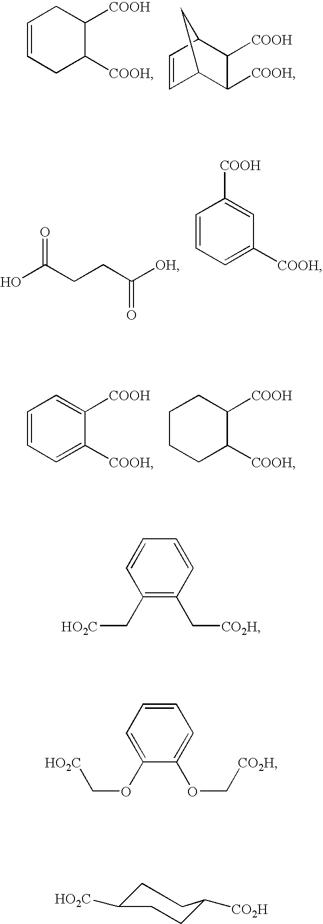

It is preferable that the fluorene-based resin polymer has a weight-average molecular weight of 1,000 to 50,000, and is contained in an amount of 1 to 30% by weight, based on the total weight of the photo-sensitive resin composition for a black matrix. If the content is less than 1% by weight, adherence of the formed film is deteriorated. If the content is more than 30% by weight, strength and sensitivity of the formed image is deteriorated.

In order to improve alkali development of the photo-sensitive resin composition for a black matrix of the present invention, the resin binder can be additionally mixed with an alkali-soluble resin binder. As the alkali-soluble binder, a homopolymer of a monomer containing an acid functional group, or a copolymer of the monomer and a monomer capable of increasing the strength of the film can be used. Further, a polymer compound prepared by polymerization of the formed copolymer and an ethylenic unsaturated compound containing an epoxy group can be used.

Non-limiting examples of the monomer containing an acid functional group include (meth)acrylic acid, crotonic acid, itaconic acid, maleic acid, fumaric acid, monomethyl maleic acid, isoprene sulfonic acid, styrene sulfonic acid, 5-norbornene-2-carboxylic acid, and one or more selected from them can be used.

Non-limiting examples of the monomer capable of copolymerizing with the monomer containing an acid functional group include styrene, chloro styrene, α-methyl styrene, vinyl toluene, 2-ethylhexyl(meth)acrylate, methyl(meth)acrylate, ethyl(meth)acrylate, butyl(meth)acrylate, benzyl(meth)acrylate, dimethylaminoethyl(meth)acrylate, isobutyl(meth)acrylate, t-butyl(meth)acrylate, cyclohexyl(meth)acrylate, dicyclopentanyl(meth)acrylate, isobornyl(meth)acrylate, 2-phenoxyethyl(meth)acrylate, tetrahydrofurfuryl(meth)acrylate, hydroxyethyl(meth)acrylate, 2-hydroxyethyl(meth)acrylate, 2-hydroxypropyl(meth)acrylate, 2-hydroxy-3-chloropropyl(meth)acrylate, 2-hydroxybutyl(meth)acrylate, 4-hydroxybutyl(meth)acrylate, dimethylaminomethyl(meth)acrylate, diethylamino(meth)acrylate, acyloctyloxy-2-hydroxypropyl(meth)acrylate, ethylhexyl acrylate, 2-methoxyethyl(meth)acrylate, 3-methoxybutyl(meth)acrylate, butoxyethyl(meth)acrylate, ethoxydiethyleneglycol(meth)acrylate, methoxytriethyleneglycol(meth)acrylate, methoxytripropyleneglycol(meth)acrylate, methoxypolyethyleneglycol(meth)acrylate, phenoxydiethyleneglycol(meth)acrylate, p-nonylphenoxypolyethyleneglycol(meth)acrylate, p-nonylphenoxypolypropyleneglycol(meth)acrylate, tetrafluoropropyl(meth)acrylate, 1,1,1,3,3,3-hexafluoroisopropyl(meth)acrylate, octafluoropentyl(meth)acrylate, heptadecafluorodecyl(meth)acrylate, tribromophenyl(meth)acrylate, β-(meth)acyloloxyethylhydrogen succinate, methyl α-hydroxymethyl acrylate, ethyl α-hydroxymethyl acrylate, propyl α-hydroxymethyl acrylate, butyl α-hydroxymethyl acrylate, N-phenylmaleimide, and N-(4-chlorophenyl)maleimide, and one or more selected from them can be used.

Further, non-limiting examples of the ethylenic unsaturated compound containing an epoxy group that is capable of polymerizing with the copolymer of the monomer capable of copolymerizing with the monomer containing an acid functional group include glycidyl (meth)acrylate, vinyl benzylglycidyl ether, vinyl glycidyl ether, allylglycidyl ether, 4-methyl-4,5-epoxypentene, γ-glycidoxy propyl trimethoxysilane, γ-glycidoxy propyl methyldiethoxysilane, γ-glycidoxy propyl triethoxy silane, and nobornyl derivatives, and one or more selected from them can be used.

The alkali-soluble resin binder preferably has an acid value of 50 to 300 KOH mg/g, and a weight-average molecular weight of 1,000 to 200,000.

Non-limiting examples of the multi-functional monomer having an ethylenic unsaturated bond contained in the photo-sensitive resin composition for a black matrix include polyethylene glycolmono(meth)acrylate, polypropylene glycolmono(meth)acrylate, phenoxyethyl(meth)acrylate, polyethylene glycol(meth)acrylate, polypropylene glycol(meth)acrylate, 1,4-butanediol diacrylate, 1,6-hexandiol diacrylate, bisphenol A diacrylate, novolacepoxy acrylate, trimethylol ethane triacrylate, trimethylol propane triacrylate, neopentyl glycol(meth)acrylate, pentaerythritol triacrylate, pentaerythritol tetraacrylate, pentaerythritol hexaacrylate, dipentaerythritol diacrylate, dipentaerythritol pentaacrylate, and dipentaerythritol hexaacrylate, and one or more selected from them can be used.

The multi-functional monomer having an ethylenic unsaturated bond is preferably contained in an amount of 1 to 30% by weight, based on the total weight of the photo-sensitive resin composition for a black matrix. If the content is less than 1% by weight, photosensitivity or the strength of the black matrix is deteriorated. If the content is more than 30% by weight, the adherence of photosensitive resin layer is excessive, whereby the strength of the black matrix is not sufficient and the loss of pattern is generated during development.

The photopolymerization initiator contained in the photo-sensitive resin composition for a black matrix functions to generate radicals by light. Non-limiting examples thereof acetophenone based compound, non-imidazole based compound, triazine-based compound, and oxime-based compound, and one or more selected from them can be used. Further, the photopolymerization initiator is preferably contained in an amount of 1 to 30% by weight, based on the total weight of the photo-sensitive resin composition.

Examples of the acetophenone based compound may include 2-hydroxy-2-methyl-1-phenylpropane-1-on(DAROCURE 1173), 1-(4-isopropylphenyl)-2-hydroxy-2-methylpropane-1-on(DAROCURE 1116), 1-[4-(2-hydroxyethoxy)-phenyl]-2-hydroxy-di-2-methyl-1-propane-1-on(Irgacure 2959), 1-hydroxycyclohexylphenylketone(IRGACURE 184), diethoxyacetophenone(first DEAP), 2,2-dimethoxy-2-phenylacetophenone(IRGACURE 651) 2,2-diethoxy-2-phenylacetophenone(UVATONE 8302), 2-methyl-(4-methylthio)phenyl-2-morpholino-1-propane-1-on(IRGACURE907), 2-benzyl-2-dimethylamino-1-(4-morpholinophenyl)-butane-1-on(IRGACURE369), benzoinethyl ether, benzoinisobutyl ether(esacure EB3), and benzoinbutyl ether(BIPE).

Examples of the non-imidazole based compound may include 2,2-bis(2-chlorophenyl)-4,4′,5,5′-tetraphenyl biimidazole, 2,2′-bis(o-chlorophenyl)-4,4′,5,5′-tetrakis(3,4,5-trimethoxyphenyl)-1,2′-biimidazole, 2,2′-bis(2,3-dichlorophenyl)-4,4′,5,5′-tetraphenyl biimidazole, and 2,2′-bis(o-chlorophenyl)-4,4,5,5′-tetraphenyl-1,2′-biimidazole.

Examples of the triazine-based compound may include 3-{4-[2,4-bis(trichloromethyl)-s-triazine-6-yl]phenylthio}propionic acid, 1,1,1,3,3,3-hexafluoroisopropyl-3-{4-[2,4-bis(trichloromethyl)-s-triazine-6-yl]phenylthio}propionate, ethyl-2-{4-[2,4-bis(trichloromethyl)-s-triazine-6-yl]phenylthio}acetate, 2-epoxyethyl-2-{4-[2,4-bis(trichloromethyl)-s-triazine-6-yl]phenylthio}acetate, cyclohexyl-2-{4-[2,4-bis(trichloromethyl)-s-triazine-6-yl]phenylthio}acetate, benzyl-2-{4-[2,4-bis(trichloromethyl)-s-triazine-6-yl]phenylthio}acetate, 3-{chloro-4-[2,4-bis(trichloromethyl)-s-triazine-6-yl]phenylthio}propionic acid, 3-{4-[2,4-bis(trichloromethyl)-s-triazine-6-yl]phenylthio}propionamide, 2,4-bis(trichloromethyl)-6-p-methoxystyryl-s-triazine, 2,4-bis(trichloromethyl)-6-(1-p-dimethylaminophenyl)-1,3,-butadienyl-s-triazine, and 2-trichloromethyl-4-amino-6-p-methoxystyryl-s-triazine.

Examples of the oxime-based compound may include 1-[9-ethyl-6-(2-methylbenzoyl)-9H-carbazol-3-yl]-1-(0-acetyloximee)ethanon(CGI-242), and 1-[4-(phenylthiol)phenyl]-2-(0-benzoyloxime)-1,2-octanedione (CGI-124) (ciba, Japan).

The photopolymerization initiator may further contain 0.01 to 5% by weight of photo-crosslinking sensitizer promoting the generation of radicals or 0.01 to 5% by weight of curing accelerator, based on the total weight of the photo-sensitive resin composition for a black matrix as an auxiliary ingredient.

Examples of the photo-crosslinking sensitizer include benzophenone-based compounds such as benzophenone, 4,4-bis(dimethylamino)benzophenone, 4,4-bis(diethylamino)benzophenone, 2,4,6-trimethylaminobenzophenone, methyl-o-benzoylbenzoate, 3,3-dimethyl-4-methoxybenzophenone, and 3,3,4,4-tetra(t-butylperoxycarbonyl)benzophenone; fluorenone-based compounds such as 9-fluorenone, 2-chloro-9-fluorenone, and 2-methyl-9-fluorenone; thioxanthonebased-compounds such as thioxanthone, 2,4-diethyl thioxanthone, 2-chloro thioxanthone, 1-chloro-4-propyloxy thioxanthone, isopropylthioxanthone, and diisopropylthioxanthone; xanthonebased-compounds such as xanthone, and 2-methylxanthone; anthraquinonebased-compounds such as anthraquinone, 2-methyl anthraquinone, 2-ethyl anthraquinone, t-butyl anthraquinone, and 2,6-dichloro-9,10-anthraquinone; acridine based-compounds such as 9-phenylacridine, 1,7-bis(9-acridinyl)heptane, 1,5-bis(9-acridinylpentane), and 1,3-bis(9-acridinyl)propane; dicarbonylbased-compounds such as benzyl, 1,7,7-trimethyl-bicyclo[2,2,1]heptane-2,3-dione, and 9,10-phenanthrenequinone; phosphine oxidebased-compounds such as 2,4,6-trimethylbenzoyl diphenylphosphine oxide, and bis(2,6-dimethoxybenzoyl)-2,4,4-trimethylpentyl phosphine oxide; amino synergists such as 2,5-bis(4-diethylaminobenzal)cyclopentanone, 2,6-bis(4-diethylaminobenzal)cyclohexanone, and 2,6-bis(4-diethylaminobenzal)-4-methyl-cyclopentanone; coumarinbased-compounds such as 3,3-carbonylvinyl-7-(diethylamino)coumarin, 3-(2-benzothiazolyl)-7-(diethylamino)coumarin, 3-benzoyl-7-(diethylamino)coumarin, 3-benzoyl-7-methoxy-coumarin, and 10,10-carbonylbis[1,1,7,7-tetramethyl-2,3,6,7-tetrahydro-1H,5H,11H-C1]-benzopyrano[6,7,8-ij]-quinolizine-11-on; chalcone compounds such as 4-diethylamino chalcone, and 4-azidebenzalacetophenone; and 2-benzoylmethylene and 3-methyl-b-naphthothiazoline, and one or more selected from them can be used.

Examples of the curing accelerator include 2-mercaptobenzoimidazole, 2-mercaptobenzothiazole, 2-mercaptobenzooxazole, 2,5-dimercapto-1,3,4-thiadiazole, 2-mercapto-4,6-dimethylaminopyridine, pentaerythritol-tetrakis(3-mercaptopropionate), pentaerythritol-tris(3-mercaptopropionate), pentaerythritol-tetrakis(2-mercaptoacetate), pentaerythritol-tris(2-mercaptoacetate), trimethylolpropane-tris(2-mercaptoacetate), and trimethylolpropane-tris(3-mercaptopropionate), and one or more selected from them can be used.

Examples of the solvent contained in the photo-sensitive resin composition for a black matrix include, in consideration of solubility, pigment dispersity, propyleneglycol monomethyl ether, ethyleneglycol monomethyl ether acetate, propyleneglycol monomethyl ether acetate, propyleneglycol monoethyl ether acetate, diethyleneglycol dimethyl ether, cyclohexanone, 2-heptanone, 3-heptanone, 2-hydroxyethylpropionate, 3-methyl-3-methoxybutylpropionate, ethyl-3-methoxypropionate, methyl-3-ethoxypropionate, ethyl-3-ethoxypropionate, butylacetate, amylpermeate, isoamylacetate, isobutylacetate, butylpropionate, isopropylbutyrate, ethylbutyrate, butylbutyrate, ethylpyruvate, and γ-butyrolacetate, and one or more selected from them can be used.

The solvent may be contained in a residual amount in the photo-sensitive resin composition for a black matrix, and the content of the solvent varies depending on the content of the ingredients contained in the photo-sensitive resin composition for a black matrix. For example, the solvent may be used in an amount of 10 to 95% by weight, based on the total weight of the photo-sensitive resin composition for a black matrix.

The photo-sensitive resin composition for a black matrix may further include one or more additives selected from dispersing agents, adhesion accelerators, antioxidants, UV absorbers, anti-thermal polymerization agents, and leveling agents, and any substance known in the related art can be used.

Specifically, the dispersing agent can be added to pigment externally or internally through surface-treatment of said pigment by the dispersing agent in advance.

Examples of the dispersing agent may include polymer type, nonionic, cationic, and anionic dispersing agents. Non-limiting examples of the dispersing agent include polyalkyleneglycol and ester thereof, polyoxyalkylene polyol, esteralkylene oxide addition product, alcoholalkyleneoxide addition product, sulfonic acid ester, sulfonate, carboxylic acid ester, carboxylate, alkylamidealkyleneoxide addition product, and alkylamine, and one or more selected from them can be used.

Non-limiting examples of the adhesion accelerator may include vinyltrimethoxysilane, vinyltriethoxysilane, vinyltris(2-methoxyethoxy)-silane, N-(2-aminoethyl)-3-aminopropylmethyldimethoxysilane, N-(2-aminoethyl)-3-aminopropylmethyltrimethoxysilane, 3-aminopropyltriethoxysilane, 3-glycidoxypropyltriethoxysilane, 3-glycidoxypropylmethyldimethoxysilane, 2-(3,4-ethoxy cyclohexyl)ethyltrimethoxysilane, 3-chloropropyl methyldimethoxysilane, 3-chloropropyl trimethoxy silane, 3-methacryl oxypropyltrimethoxysilane, and 3-mercaptopropyltrimethoxysilane, and one or more selected from them can be used.

Non-limiting examples of the antioxidant may include 2,2-thiobis(4-methyl-6-t-butylphenol), and 2,6-g,t-butylphenol, and one or more selected from them can be used.

Non-limiting examples of the UV absorber may include 2-(3-t-butyl-5-methyl-2-hydroxyphenyl)-5-chloro-benzotriazole, and alkoxy benzophenone, and one or more selected from them can be used.

Non-limiting examples of the anti-thermal polymerization agent may include hydroquinone, p-methoxyphenol, di-t-butyl-p-cresol, pyrogallol, t-butylcatechol, benzoquinone, 4,4-thiobis(3-methyl-6-t-butylphenol), 2,2-methylenebis(4-methyl-6-t-butylphenol), and 2-mercaptoimidazole, and one or more selected from them can be used.

For the preparation of the photo-sensitive resin composition for a black matrix of the present invention, a pigment dispersing solution that is capable of being used as the light shielding material is first prepared. In this connection, a pigment that is commercially available in the form of dispersing solution can be used. The resin binder is mixed with the pigment dispersing solution, and the multi-functional monomer having an ethylenic unsaturated bond, photopolymerization initiator and solvent are added thereto. Stirring is performed to prepare the photo-sensitive resin composition for a black matrix.

Further, the present invention provides a black matrix produced by the photo-sensitive resin composition for a black matrix. The black matrix can be prepared by the following method.

The photo-sensitive resin composition for a black matrix is coated to the surface of substrate, and pre-baked to remove the solvent, resulting in a film. Examples of the coating method may include a spray method, a roll coating method, a spin coating method, a bar coating method, and a slit coating method. The pre-baking can be generally performed under the condition of 70 to 150° C. for 0.5 to 30 minutes, depending on combination ingredients and ratio of the composition.

Next, the pre-baked coating film is subjected to UV radiation through a predetermined pattern mask, and developed by an alkali aqueous solution to remove the unnecessary region, resulting in a pattern. For the development, a dipping method, a shower method or the like can be employed without any limitation. The development is generally performed for 30 to 180 seconds.

Examples of the developing solution include, as an alkali aqueous solution, inorganic alkali such as sodium hydroxide, potassium hydroxide, sodium silicate, sodium metasilicate, and ammonia; primary amines such as ethylamine, and N-propylamine; secondary amines such as diethylamine, and di-n-propylamine; tertiary amines such as trimethylamine, methyldiethylamine, and dimethylethylamine; tertiary alcohol amines such as dimethylethanolamine, methyldiethanolamine, and triethanolamine; cyclic tertiary amines such as pyrrol, piperidine, n-methylpiperidine, n-methylpyrrolidine, 1,8-diazabicyclo[5.4.0]-7-undecene, and 1,5-diazabicyclo[4.3.0]-5-nonene; aromatic tertiary amines such as pyridine, collidine, lutidine, and quinoline; and quaternary ammonium salts such as tetramethylammoniumhydroxide and tetraethylammoniumhydroxide.

After development, washing is performed with flowing water for about 30 to 90 seconds, and drying is performed with air or nitrogen to form a pattern. The pattern is post-baked using a heating machine such as hot plate and oven to obtain a black matrix. In this connection, the post-baking is preferably performed under the condition of 150 to 230° C. for 10 to 90 minutes.

The prepared black matrix has a sufficient light-shielding property, and its optical density (OD) is 3.5 or more at a thickness of 1.2 μm, and preferably 4.0 or more at a thickness of 1.2 μm.

The present invention provides a color filter comprising the black matrix.

Further, the present invention provides a liquid crystal display comprising the black matrix.

### MODE FOR INVENTION

Hereinafter, the present invention will be described in detail in light of Examples. The present invention may, however, be embodied in many different forms and should not be construed as being limited to the Examples set forth herein. Rather, these Examples are provided such that this disclosure will be thorough and complete and will fully convey the concept of the present invention to those skilled in the art.

### Preparation Example 1

122 g of 9,9-bisphenolfluorenediglycidylether and 45 g of 4-cyclohexene-1,2-dicarboxylic acid were stirred with 150 g of propyleneglycol methyl ether acetate. While supplying oxygen into a reactor, the reactor was heated to 110° C. After 10 hours, the reaction was completed, and 200 g of reaction solvent was added to give a resin binder of the present invention. (solid content: 29.19%, acid value: 25, molecular weight: 13000)

### Preparation Example 2

124 g of 9,9-bisphenolfluorenediglycidylether and 44 g of phthalic acid were stirred with 150 g of propyleneglycol methyl ether acetate. While supplying oxygen into a reactor, the reactor was heated to 110° C. After 10 hours, the reaction was completed, and 200 g of reaction solvent was added to give a resin binder of the present invention. (solid content: 28.80%, acid value: 32, molecular weight: 10300)

### Preparation Example 3

107 g of 9,9-bisphenolfluorenediglycidylether and 42 g of 5-norbornene-2,3-dicarboxylic acid were stirred with 150 g of propyleneglycol methyl ether acetate. While supplying oxygen into a reactor, the reactor was heated to 110° C. After 10 hours, the reaction was completed, and 200 g of reaction solvent was added to give a resin binder of the present invention. (solid content: 31.65%, acid value: 25, molecular weight: 4000)

### Preparation Example 4

90 g of 9,9-bisphenolfluorenediglycidylether and 30 g of succinic acid were stirred with 180 g of propyleneglycol methyl ether acetate. While supplying oxygen into a reactor, the reactor was heated to 110° C. After 10 hours, the reaction was completed to give a resin binder used as Comparative Example of the present invention. (solid content: 40.91%, acid value: 95, molecular weight: 2400)

Part by weight of the following Example 1 was based on 1000 parts by weight of the photo-sensitive resin composition for a black matrix.

### Example 1

### Preparation of Photo-Sensitive Resin Composition for a Black Matrix

30 parts by weight of the fluorene-based resin binder (solid content: 30% by weight, 70% by weight of propyleneglycol methyl ether acetate) as a rein of Preparation Example 1, 60 parts by weight of a polymer (molar ratio: 73/19/8, Mw=22,000), in which glycidyl methacrylate was added to a copolymer of benzyl(meth)acrylate/(meth)acrylic acid, as an alkali-soluble resin binder (solid content: 30% by weight, 70% by weight of propyleneglycol methyl ether acetate), 80 parts by weight of dipentaerythritolhexaacrylate (solid content: 50% by weight, 50% by weight of propyleneglycol methyl ether acetate) as a monomer were mixed with 375 parts by weight of carbon black dispersing solution (solid content: 20% by weight of carbon black, 3% by weight of dispersing agent, 4% by weight of a copolymer of benzyl(meth)acrylate/(meth)acrylic acid (molar ratio: 70/30, Mw=23,000), and 73% by weight of propyleneglycol methyl ether acetate), and were mixed with 4 parts by weight of 2-benzyl-2-(dimethylamino)-1-(4-morpholinophenyl)butyl-1-on (trade name: Irgacure 369), 5 parts by weight of 1-[9-ethyl-6-(2-methylbenzoyl)-9H-carbazol-3-yl]-1-(0-acetyloxime)ethanon (trade name: CGI-242), 4 parts by weight of 2,2′-bis(o-chlorophenyl)-4,4,5,5′-tetraphenyl-1,2′-biimidazole, 4 parts by weight of 4,4-bis(diethylamino)benzophenone, and 2 parts by weight of mercaptobenzothiazole as a photopolymerization initiator. 5 parts by weight of 3-methacryl oxypropyltrimethoxysilane as an adhesion accelerator and 1 part by weight of leveling agent were mixed therewith. As a solvent, 150 parts by weight of propylene glycol monomethyl ether acetate, 140 parts by weight of 3-methoxy butyl acetate, and 140 parts by weight of dipropylene glycol monomethyl ether were mixed therewith. Then, the mixture was stirred for 5 hours to prepare a photo-sensitive resin composition for a black matrix.

### Example 2

A photo-sensitive resin composition for a black matrix was prepared with the same composition and in the same manner as in Example 1, except using the fluorene-based resin binder of Preparation Example 2.

### Example 3

A photo-sensitive resin composition for a black matrix was prepared with the same composition and in the same manner as in Example 1, except using the fluorene-based resin binder of Preparation Example 3.

### Example 4

A photo-sensitive resin composition for a black matrix was prepared with the same composition and in the same manner as in Example 1, except using the fluorene-based resin binder of Preparation Example 4.

### Comparative Example 1

A photo-sensitive resin composition for a black matrix was prepared with the same composition as in Example 1, except using a copolymer of benzyl(meth)acrylate/(meth)acrylic acid (molar ratio: 73/27, Mw=23,000) instead of the fluorene-based resin binder.

### Experimental Example 1

### Formation of Black Matrix Pattern

Each solution of photo-sensitive resin composition for a black matrix prepared in Examples 1 to 4 and Comparative Example 1 was applied on a glass by spin-coating, and pre-heated at about 110° C. for 2 minutes to form a film having a thickness of about 1.3 μm. Next, the film was cooled to room temperature, and then exposed at an exposure gap of 100 μm with an energy of 60 mJ/cm² through a photomask under a high pressure mercury lamp. The exposed substrate was developed using a 0.04% KOH aqueous solution at 25° C. by spraying method, and then washed with purified water. The substrate was dried, and post-baked at 220° C. in an oven for 30 minutes to form a black matrix pattern.

Measurement of Sensitivity and Light-Shielding Property

In the formation of the black matrix, a thickness was measured using a film thickness gauge before alkali development. The light dose was gradually increased from 20 mJ to 10 mJ, and then the development was performed in an alkali aqueous solution. Then, the thickness was measured again, and a residual film ratio was measured according to the exposure dose to obtain a minimum exposure dose, at which the residual film ratio was saturated. The results are shown in Table 1. Further, OD was measured using an optical densitometer (Macbeth D200-II), and the results are shown in the following Table 1.

Measurement of Development Adherence

Radiation was performed at the minimum exposure dose obtained in the sensitivity measurement. Development was performed using an alkali aqueous solution for a predetermined time, and the obtained minimum pattern size according to the development time is shown in Table 2.

TABLE 1

| | | Light- | | | |
|---|---|---|---|---|---|
| | | shielding | | | |
| | Thickness | property | | Taper | Sensitivity |
| | (μm) | (OD) | straightness | angle | (mJ/cm²) |
| Example 1 | 1.2 | 4.5 | ⊚ | 40 or less | 60 |
| Example 2 | 1.2 | 4.5 | ◯ | 50 or less | 60 |
| Example 3 | 1.2 | 4.5 | ◯ | 50 or less | 60 |
| Example 4 | 1.2 | 4.5 | Δ | 70 or less | 60 |
| Comp- | 1.2 | 4.5 | Δ | 70 or less | 80 |
| arative | | | | | |
| Example 1 | | | | | |

⊚: very good
◯: good
Δ: fair
X: poor

TABLE 2

Residual minimum pattern size
according to development
time (μm)

| | 60 sec | 70 sec | 80 sec | 90 sec |
|---|---|---|---|---|
| Example 1 | 3 | 4 | 7 | 10 |
| Example 2 | 3 | 5 | 8 | 11 |
| Example 3 | 4 | 6 | 9 | 13 |
| Example 4 | 7 | 11 | 15 | 20 |
| Comparative | 8 | 11 | 16 | 25 |
| Example 1 | | | | |

The black matrix pattern of the present invention obtained as above has a thickness of 1.2 μm, and no pattern loss, no taint on the unexposed portion, and excellent pattern straightness and surface flatness were confirmed by an optical microscope (OLYMPUS BX60F-3).

1. A photo-sensitive resin composition for a black matrix, comprising
a) 1 to 70% by weight of a light shielding material containing a coloring agent;
b) 1 to 30% by weight of a resin binder having a repeating unit of the following Formula 1;
c) 1 to 30% by weight of a multi-functional monomer having an ethylenic unsaturated bond;
d) 1 to 30% by weight of a photopolymerization initiator; and
e) a residual amount of a solvent 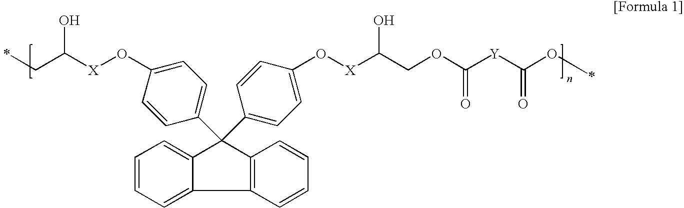
wherein X is one selected from the group consisting of alkylene having 1 to 3 carbon atoms, ethylene oxide and propylene oxide, and
Y is one selected from the group consisting of cyclohexane, cyclohexene, benzene, and alkylene having 1 to 3 carbon atoms.

2. The photo-sensitive resin composition for a black matrix according to claim 1, wherein the coloring agent comprises at least one selected from organic pigments consisting of black pigment including carbon black or titan black, red pigment, yellow pigment, blue pigment and violet pigment.

3. The photo-sensitive resin composition for a black matrix according to claim 1, wherein the resin binder is prepared by condensation reaction of a diepoxy compound containing a fluorene group, represented by the following Formula 3 and a diacid compound having such a structure that both ends of one selected from benzene, cyclohexane, cyclohexene, norbornene and alkane having 3 to 10 carbon atoms are substituted with two acids; 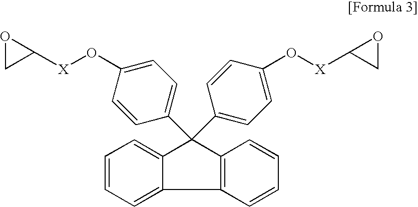
wherein X is one selected from alkylene having 1 to 3 carbon atoms, ethylene oxide and propylene oxide.

4. The photo-sensitive resin composition for a black matrix according to claim 3, wherein the resin binder is additionally mixed with an alkali-soluble resin binder including a copolymer of a monomer containing an acid functional group and a monomer capable of copolymerizing the monomer; or a polymer compound formed by binding an ethylenic unsaturated compound containing an epoxy group to the copolymer.

5. The photo-sensitive resin composition for a black matrix according to claim 4, wherein the monomer containing an acid functional group is a mixture of one or more selected from (meth)acrylic acid, crotonic acid, itaconic acid, maleic acid, fumaric acid, monomethyl maleic acid, isoprene sulfonic acid, styrene sulfonic acid, 5-norbornene-2-carboxylic acid.

6. The photo-sensitive resin composition for a black matrix according to claim 4, wherein the monomer capable of copolymerizing with the monomer containing an acid functional group is at least one selected from styrene, chloro styrene, α-methyl styrene, vinyl toluene, 2-ethylhexyl(meth)acrylate, methyl(meth)acrylate, ethyl(meth)acrylate, butyl(meth)acrylate, benzyl(meth)acrylate, dimethylaminoethyl(meth)acrylate, isobutyl(meth)acrylate, t-butyl(meth)acrylate, cyclohexyl(meth)acrylate, dicyclofentanyl(meth)acrylate, isobornyl(meth)acrylate, 2-phenoxyethyl(meth)acrylate, tetrahydrofurfuryl(meth)acrylate, hydroxyethyl(meth)acrylate, 2-hydroxyethyl(meth)acrylate, 2-hydroxypropyl(meth)acrylate, 2-hydroxy-3-chloropropyl(meth)acrylate, 2-hydroxybutyl(meth)acrylate, 4-hydroxybutyl(meth)acrylate, dimethylaminomethyl(meth)acrylate, diethylamino(meth)acrylate, acyloctyloxy-2-hydroxypropyl(meth)acrylate, ethylhexyl acrylate, 2-methoxyethyl(meth)acrylate, 3-methoxybutyl(meth)acrylate, butoxyethyl(meth)acrylate, ethoxydiethyleneglycol(meth)acrylate, methoxytriethyleneglycol(meth)acrylate, methoxytripropyleneglycol(meth)acrylate, methoxypolyethyleneglycol(meth)acrylate, phenoxydiethyleneglycol(meth)acrylate, p-nonylphenoxypolyethyleneglycol(meth)acrylate, p-nonylphenoxypolypropyleneglycol(meth)acrylate, tetrafluoropropyl(meth)acrylate, 1,1,1,3,3,3-hexafluoroisopropyl(meth)acrylate, octafluoropentyl(meth)acrylate, heptadecafluorodecyl(meth)acrylate, tribromophenyl(meth)acrylate, β-(meth)acyloloxyethylhydrogen succinate, methyl α-hydroxymethyl acrylate, ethyl α-hydroxymethyl acrylate, propyl α-hydroxymethyl acrylate, butyl α-hydroxymethyl acrylate, N-phenylmaleimide and N-(4-chlorophenyl)maleimide.

7. The photo-sensitive resin composition for a black matrix according to claim 4, wherein the alkali-soluble resin binder has an acid value of 50 to 300 KOH mg/g, and a weight-average molecular weight of 1,000 to 200,000.

8. The photo-sensitive resin composition for a black matrix according to claim 1, wherein the multi-functional monomer having an ethylenic unsaturated bond comprises at least one selected from polyethylene glycolmono(meth)acrylate, polypropylene glycolmono(meth)acrylate, phenoxyethyl(meth)acrylate, polyethylene glycol(meth)acrylate, polypropylene glycol(meth)acrylate, 1,4-butanediol diacrylate, 1,6-hexandiol diacrylate, bisphenolA diacrylate, novolacepoxy acrylate, trimethylol ethane triacrylate, trimethylol propane triacrylate, neopentyl glycol(meth)acrylate, pentaerythritol triacrylate, pentaerythritol tetraacrylate, pentaerythritol hexaacrylate, dipentaerythritol diacrylate, dipentaerythritol pentaacrylate and dipentaerythritol hexaacrylate.

9. The photo-sensitive resin composition for a black matrix according to claim 1, wherein the photo-sensitive resin composition for a black matrix further comprises at least one selected from photo crosslinking sensitizer, curing accelerator dispersing agent, adhesion accelerator, antioxidant, UV absorber, anti-thermal polymerization agent and leveling agent.

10. The photo-sensitive resin composition for a black matrix according to claim 1, wherein the solvent comprises a mixture of one or more selected from propyleneglycol monomethyl ether, ethyleneglycol monomethyl ether acetate, propyleneglycol monomethyl ether acetate, propyleneglycol monoethyl ether acetate, diethyleneglycol dimethyl ether, cyclohexanone, 2-heptanone, 3-heptanone, 2-hydroxyethylpropionate, 3-methyl-3-methoxybutylpropionate, ethyl-3-methoxypropionate, methyl-3-ethoxypropionate, ethyl-3-ethoxypropionate, butylacetate, amyl permeate, isoamylacetate, isobutylacetate, butylpropionate, isopropylbutyrate, ethylbutyrate, butylbutyrate, ethylpyruvate and γ-butyrolacetate.

11. A black matrix produced by the photo-sensitive resin composition for a black matrix of claim 1.

12. A color filter comprising the black matrix of claim 11.

13. A liquid crystal display comprising the black matrix of claim 11.
